(19) United States
(12) Patent Application Publication
(10) Pub. No.: US 2024/0395666 A1
(43) Pub. Date: Nov. 28, 2024

(54) THROUGH SILICON VIA WITH TEXTURED STRUCTURE AND FOOTING FEATURES

(71) Applicant: Taiwan Semiconductor Manufacturing Company, Ltd., Hsin-Chu (TW)

(72) Inventors: Yao-Chun Chuang, Hsinchu City (TW); Tsung-Yu Ke, Nantou County (TW); Chang-Jung Hsueh, Taipei (TW); Min-Feng Ku, Hsinchu City (TW); Jun He, Hsinchu County (TW)

(21) Appl. No.: 18/474,606

(22) Filed: Sep. 26, 2023

Related U.S. Application Data
(60) Provisional application No. 63/503,574, filed on May 22, 2023.

(51) Int. Cl. H01L 23/48; H01L 21/768; H01L 23/532

(52) U.S. Cl. CPC H01L 23/481; H01L 21/76873; H01L 21/76877; H01L 21/76898; H01L 23/53238

(57) ABSTRACT

The present disclosure provides a semiconductor structure. The semiconductor structure includes a metal line over a first substrate, a second substrate over the metal line, and a through-via penetrating through the second substrate and landing on the metal line. The through-via includes a copper fill having at least 85% (111) crystal orientation. The through-via includes a top portion with a first top width over a bottom portion with a second top width that is smaller than the first top width, and the top portion includes a first bulk portion over a first footing feature. The first bulk portion has first sidewalls, the first footing feature has second sidewalls, and the second sidewalls slant inwards from the first sidewalls to narrow the through-via from the first top width of the top portion to the second top width of the bottom portion.

### PRIORITY DATA

This application claims the benefit of U.S. Provisional Application No. 63/503,574 filed May 22, 2023, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One advancement is in the use of through silicon vias (TSVs), which may also be referred to as through-wafer vias, through-substrate vias, feedthrough vias, or through-vias generally. TSV technology overcome limitations of wire bonding and allows for direct metal interconnections to create stacked 3D ICs having stacked wafers, stacked dies, and/or combinations thereof. TSVs allow for shorter interconnects by forming an interconnect in the z-axis. The interconnect is created through a substrate (e.g. wafer), by forming a via extending from a front surface to a back surface of the substrate. This allows for flexibility in forming semiconductor features on both front and backsides of a semiconductor structure. In one example, the TSVs may electrically connect frontside source/drain features to a backside power rail.

However, although existing methods of forming TSVs have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a through-via having footing features, according to an embodiment of the present disclosure.

FIG. 2A illustrates a flow chart of a method to form a through-via having footing features, according to an embodiment of the present disclosure.

FIG. 2B illustrates a flow chart of a method to form a through-via trench having tapered sidewalls, according to an embodiment of the present disclosure.

FIGS. 3-11 illustrate the formation of a through-via having footing features at intermediate stages of fabrication, processed in accordance with the methods of FIGS. 2A and 2B, according to an embodiment of the present disclosure.

FIGS. 12-14 illustrates a through-via having footing features and various texture schemes according to other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximately,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, can be understood to be within +/−10% between the compared features. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to through silicon vias (TSVs). TSVs are often prone to thermal reliability issues, causing risks in subsequent back-end-of-line (BEOL) and die-stacking processes. As part of the IC manufacturing process, the TSVs are subjected to repeated thermal loadings, and the thermal stress accumulation during the different thermal annealing steps may cause plastic deformation in the TSV metal (e.g., copper). The plastic deformation causes metal protrusion due to the TSV metal expanding and extruding out of the substrate surface. This in turn causes fracture or cracking of the dielectric layer over the TSV, threatening the IC interconnection layer and adversely affecting circuit performance.

As such, the present disclosure describes various embodiments of TSVs having a textured structure with high (111) crystal orientations. The TSVs are made of copper, and the high (111) crystal orientation provides high thermal stability, which reduces defects caused by TSV thermal protrusions. With high (111) crystal orientation, the grain growth of the copper remains unchanged up to 300° C. for one hour. To effectuate high (111) crystal orientations, the present disclosure provides a TSV profile having various taper footing features, tuned for suitable copper growth orientation. The multiple taper footing features also function to redirect and spread out thermal stress, thereby also reducing thermal protrusion.

Although TSVs are referred to as through silicon vias, for purposes of the present disclosure, TSVs also refer to through-wafer vias, through-substrate vias, through-dielectric vias, feedthrough vias, or through-vias generally. As such, the TSVs may penetrate through one or more semiconductor materials, dielectric materials, and/or conductive materials. The TSVs bypass circuitry to directly connect components from one side of a substrate to an opposite side of the substrate.

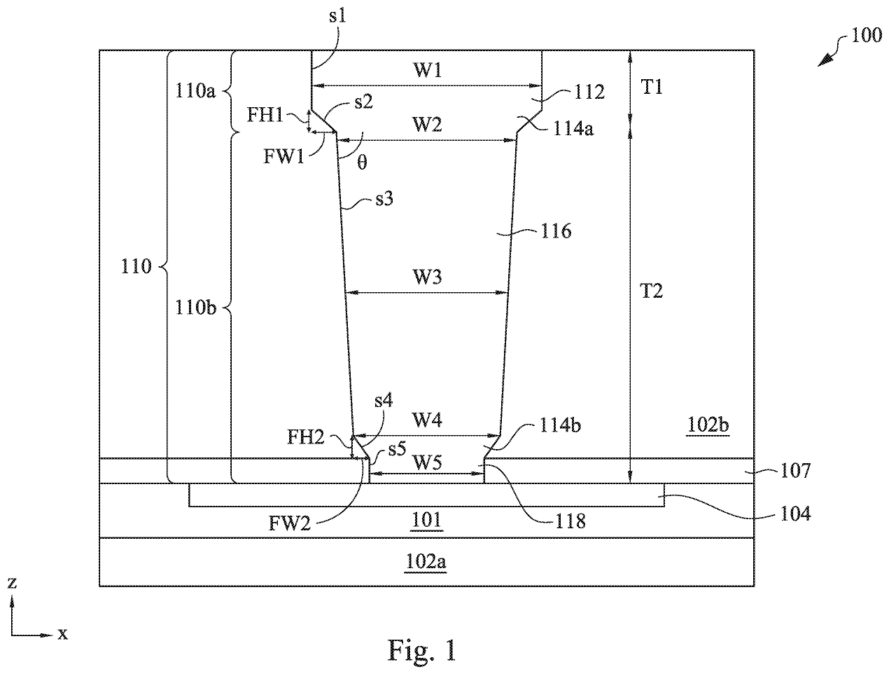

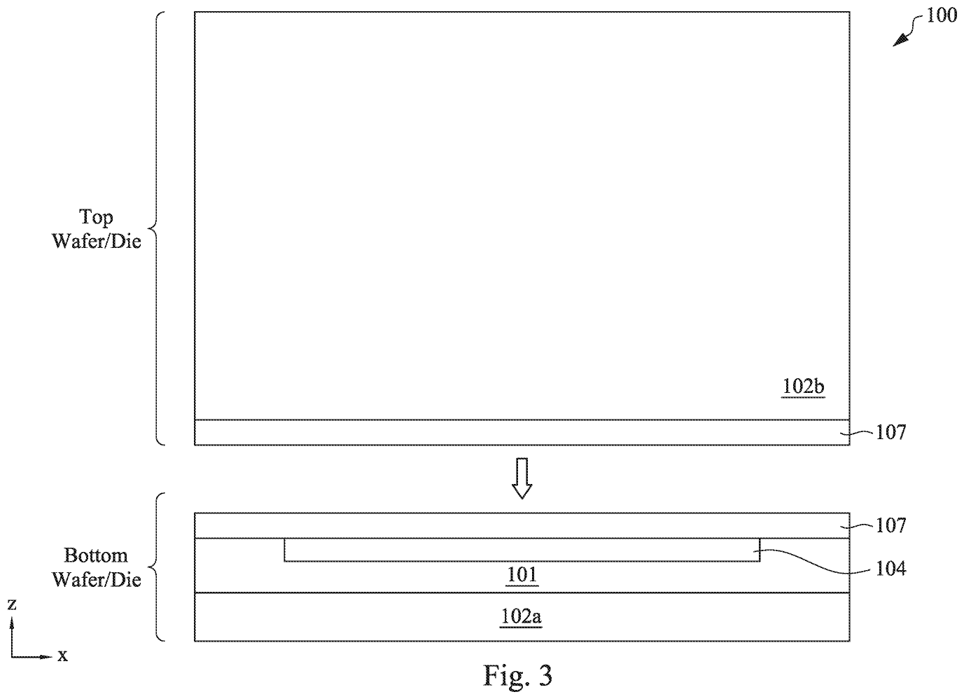

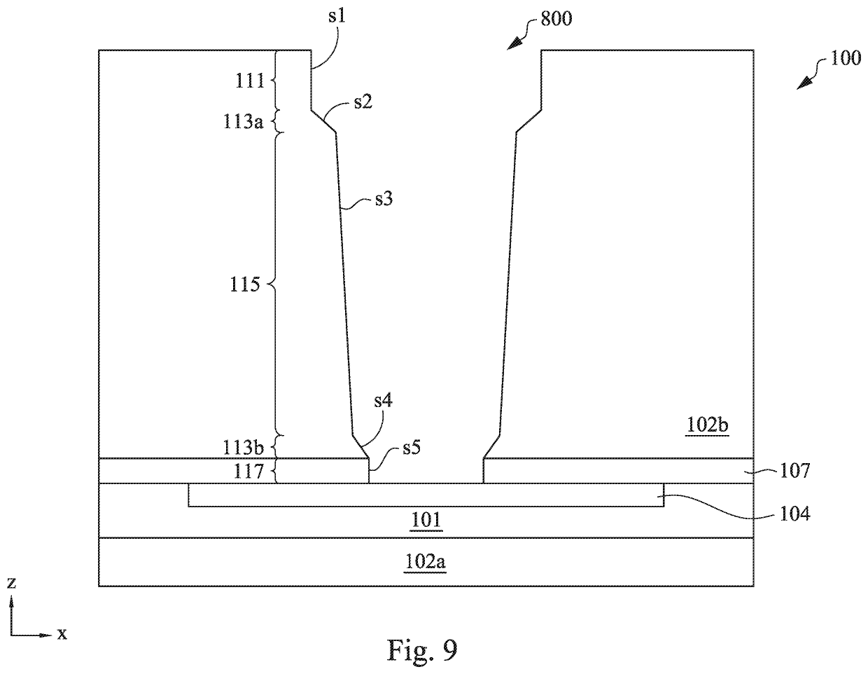

FIG. 1 illustrates a through-via 110 (or TSV 110) having footing features 114a and 114b. For case of describing various dimensions, the TSV 110 omits certain features, which will be described in later figures (e.g., FIGS. 9-13). The TSV 110 is part of a semiconductor structure 100, which may include various active and passive components, including but not limited to transistors, capacitors, resistors, metal routings, vias, and other circuit structures. In an embodiment, the semiconductor structure 100 includes a first substrate 102a, an intermetal dielectric 101 over the first substrate 102a, a metal line 104 over the first substrate 102a and embedded in the intermetal dielectric 101, a dielectric layer 107 over the metal line 104 and the intermetal dielectric 101, and a second substrate 102b over the dielectric layer 107. The TSV 110 penetrates through the second substrate 102b and the dielectric layer 107 to land on the metal line 104. In an embodiment, the first substrate 102a and the second substrate 102b are substrates for different wafers or dies, and the different wafers or dies are bonded together in a chip bonding process. As described in FIG. 3, the chip bonding process may be an adhesive bonding process through the dielectric layer 107. In an embodiment, the first substrate 102a may be a substrate for a support wafer, and the second substrate 102b may be a substrate for a functional chip. In another embodiment, both the first substrate 102a and the second substrate 102b are substrates for functional chips.

Still referring to FIG. 1, the TSV 110 includes a wider top portion 110a over a narrower bottom portion 110b. The wider top portion 110a allows better spacing margins for other components to land on, and the narrower bottom portion 110b can be thinner to save space. The top portion 110a has a thickness T1, and the bottom portion 110b has a thickness T2. The thickness T1 may be in a range between about 0.5 μm to about 2.5 μm. The thickness T2 may be in a range between about 1.5 μm to about 10 μm. In an embodiment, the thickness T2 is greater than the thickness T1. The top portion 110a has a top width W1, and the bottom portion 110b has a top width W2. The top width W1 is greater than the top width W2. In an embodiment, the width W1 ranges between about 1.4 μm to about 10 μm, and the width W2 ranges between about 0.6 μm to about 8 μm. In an embodiment, a ratio of W2 to W1 is in a range between about 0.4 to about 0.8.

Still referring to FIG. 1, the top portion 110a further includes a bulk portion 112 over a footing feature 114a. The bulk portion 112 has first sidewalls s1 and the bulk portion 112 has the top width WI between the first sidewalls s1. The footing feature 114a has second sidewalls s2 and the second sidewalls s2 slant inwards towards a center of the TSV 110. Specifically, the second sidewalls s2 slant inwards from the first sidewalls s1 to narrow the TSV 110 from the width W1 to the width W2. The footing feature 114a has a first foot height FH1 and a first foot width FW1. The first foot height FH1 is the thickness (or height) of the footing feature 114a. The first foot width FW1 is a lateral distance of one of the second sidewalls s2. As shown, the first foot width FW1, the first foot height FH1, and a sidewall s2 defines a right triangle, where the sidewall s2 is the hypotenuse. In an embodiment, the footing feature 114a has an upside-down trapezoidal shape. The trapezoidal shape includes the width W1 on a top side of the trapezoid that narrows to a width W2 on a bottom side of the trapezoid.

As such, the foot width FW1 may also be defined by a difference between W1 and W2 divided by 2. The foot height FH1 may be in a range between about 0.1 μm to about 1 μm, and the foot width FW1 may be in a range between about 0.4 μm to about 1 μm. In an embodiment, the foot width FW1 should be greater than the foot height FH1. This will achieve a greater amount of narrowing within a shorter amount of vertical distance, which is desirable in certain applications to reduce total TSV height. A difference between the thickness T1 and the foot height FH1 may define a height of the bulk portion 112. The height of the bulk portion 112 may be in a range between about 0.4 μm to about 1.5 μm.

Still referring to FIG. 1, the bottom portion 110b further includes a bulk portion 116 over a footing feature 114b. In the embodiment shown, the bottom portion 110b further includes a landing portion 118 below the footing feature 114b. The bulk portion 116 has third sidewalls s3 and the third sidewalls s3 may be slightly tilted inwards towards a center of the TSV 110. Instead of a 90-degree vertical sidewall, the third sidewalls s3 have a taper angle ⊖ between about 68 degree to about 88 degree (as shown). Due to the tilt, the bulk portion 116 has a wider portion towards the top and a narrower portion towards the bottom. As shown, the bulk portion 116 has the top width W2 which narrows down to a middle width W3, which then narrows down to a bottom width W4. The width W3 is the width at a middle point of the bulk portion 116 along the y direction. In an embodiment, the width W3 ranges between about 0.5 μm to about 7.5 μm. As described above, the width W2 ranges between about 0.6 μm to about 8 μm. In an embodiment, a ratio between W3 to W2 is between about 0.8 to about 0.95. The width W4 is the width at a bottommost point of the bulk portion 116 along the y direction, which equals a top width of the footing feature 114b. In an embodiment, the width W4 ranges between about 0.4 μm to about 7 μm. In an embodiment, a ratio between W4 to W2 is between about 0.65 to about 0.9.

Still referring to FIG. 1, the footing feature 114b has fourth sidewalls s4 and the fourth sidewalls s4 slant inwards towards a center of the TSV 110. Specifically, the fourth sidewalls s4 slant inwards from the third sidewalls s3 to narrow the TSV 110 from the width W4 to a width W5. The width W5 is a bottom width of the footing feature 114b and a top width of the landing portion 118. The width W5 may be in a range between about 0.3 μm to about 6.4 μm. In an embodiment, a ratio of W5 to W4 is in a range between about 0.75 to about 0.9. The footing feature 114b has a second foot height FH2 and a second foot width FW2. The second foot height FH2 is the thickness (or height) of the footing feature 114b. The second foot width FW2 is a lateral distance of one of the fourth sidewalls s4. As shown, the second foot width FW2, the second foot height FH2, and a sidewall s4 defines a right triangle, where the sidewall s4 is the hypotenuse. In an embodiment, the footing feature 114b has an upside-down trapezoidal shape. The trapezoidal shape includes the width W4 on a top side of the trapezoid narrowing to the width W5 on a bottom side of the trapezoid. As such, the foot width FW2 may also be defined by a difference between W4 and W5 divided by 2. The foot height FH2 may be in a range between about 0.1 μm to about 1 μm, and the foot width FW2 may be in a range between about 0.1 μm to about 0.6 μm. Note that the foot width FW2 may be smaller than the foot width FW1 while the foot height FH2 is similar to the foot height FH1. As such, the second sidewalls s2 may tilt more inwards than the fourth sidewalls s4. This is because a difference between the width W1 and W2 may be bigger than a difference between the width W4 and W5.

Still referring to FIG. 1, the landing portion 118 lands on the metal line 104 and has the width W5. The landing portion 118 has a height substantially equal to a height of the dielectric layer 107. In other words, the landing portion 118 is the portion of the TSV 110 that penetrates through the dielectric layer 107. In an embodiment, the height of the landing portion 118 is less than the foot heights FH1 and FH2.

As shown in FIG. 1 and as described above, the TSV 110 includes various widths and sidewall profiles. The various widths and sidewall profiles are designed to promote high (111) copper crystal orientation, which is desirable to reduce defects caused by thermal protrusions. In the embodiment shown, the sidewalls s1 and s3 are vertical or near-vertical sidewalls (i.e., 90 degrees with respect to x axis), the sidewall s3 is a tilted sidewall (i.e., s3 is between 68 to 88 degrees below the positive x axis), and the sidewalls s2 and s4 are highly tilted sidewalls (i.e., s2 and s4 are less than 68 degrees below the positive x axis). In an embodiment, the sidewalls s2 are even more tilted than the sidewalls s4. This is because the first foot width FW1 may be bigger than the second foot width FW2 for transitioning to the wider width W1. As will be explained in more detail below, the various combinations of slanted sidewalls allows for non-abrupt changes in via formation, thereby promoting highly (111) textured electroplating growth.

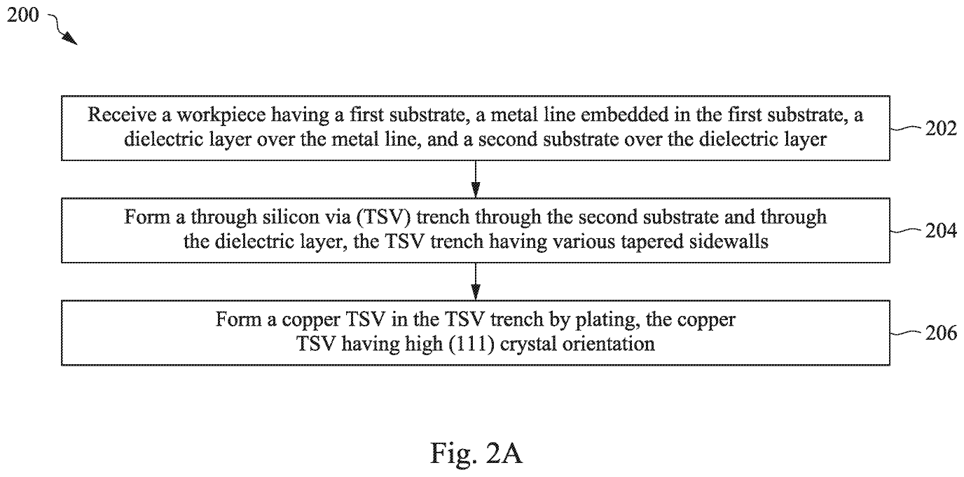

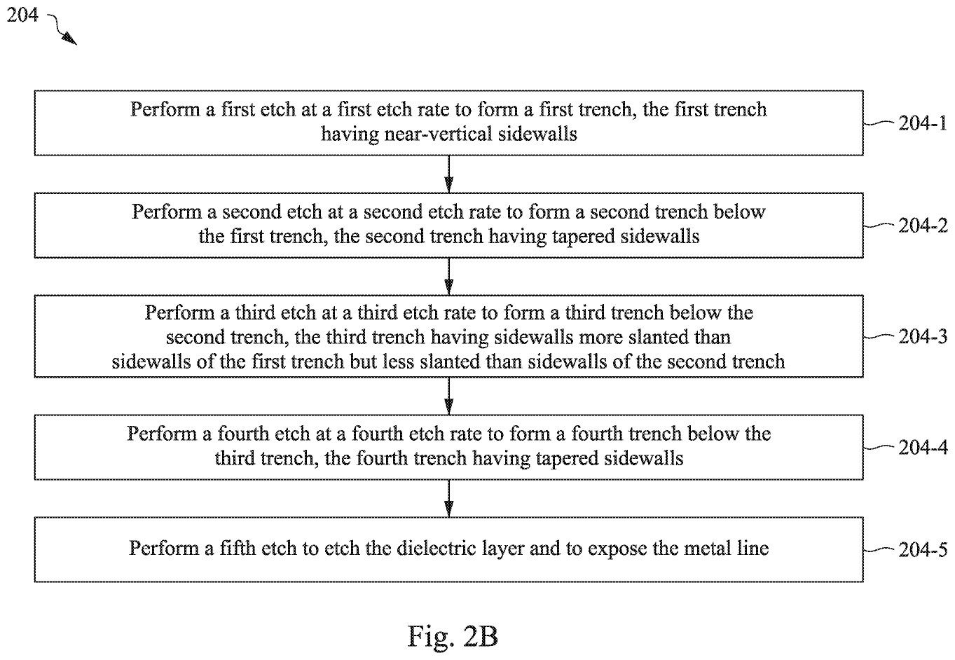

FIG. 2A illustrates a flow chart of a method 200 to form a through-via (TSV) 110 having footing features 114a and 114b. The method 200 includes operation 204, which includes forming a TSV trench having tapered sidewalls. FIG. 2B breaks down the operation 204 into additional steps 204-1 to 204-5. FIGS. 3-11 illustrate the formation of a through-via 110 having footing features 114a and 114b at intermediate stages of fabrication, processed in accordance with the method 200 according to FIGS. 2A and 2B.

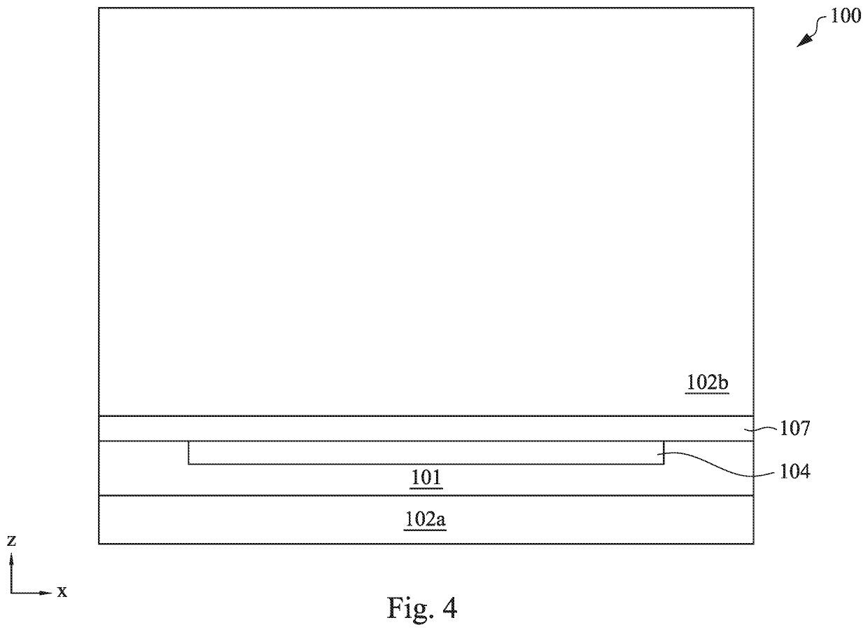

Referring now to FIGS. 3-4, the method 200 at operation 202 receives a workpiece part of a semiconductor structure 100. Referring to FIG. 3, the workpiece may be formed by a chip bonding process such as adhesive bonding, direct oxide bonding, metal bonding, or hybrid bonding. In the present embodiment, the workpiece is formed through an adhesive bonding process. For example, the dielectric layers 107 are adhesive dielectric layers that glue a top wafer or die to the bottom wafer or die. In other embodiments, the top wafer/die and the bottom wafer/die are bonded together without an adhesive layer, such as by direct oxide bonding (oxide-to-oxide), direct metal bonding (metal-to-metal), or hybrid bonding (oxide-to-oxide and metal-to-metal). In the present embodiment, the bonding is from the backside of the top wafer (or die) to the frontside of the bottom wafer (or die) (i.e., back-to-front). However, the present disclosure is not limited to any specific bonding orientations. In other embodiments, the bonding may include other bonding orientations such as front-to-front, back-to-back, or front-to-back.

Referring to FIG. 4, the workpiece includes a first substrate 102a, a metal line 104 over the first substrate 102a, a dielectric layer 107 over the metal line 104, and a second substrate 102b over the dielectric layer 107. The metal line 104 may be embedded in an intermetal dielectric 101 over the first substrate 102, where top surfaces of the intermetal dielectric 101 and the metal line 104 are substantially coplanar. Although shown as a separate feature, the intermetal dielectric 101 may also be referred to as a part of the first substrate 102a. The first substrate 102a may be a bottom substrate for a bottom device. The first substrate 102a may embed or include other features not shown, such as active regions, interlayer dielectric layers, passivation layers, and/or other metal lines or vias. The metal line 104 may be a top metal line of the first substrate 102a. Alternatively, the metal line 104 may be a metal bump or landing pad of the first substrate 102a. The dielectric layer 107 may be a bonding adhesive layer that glues the first substrate 102a to the second substrate 102b. The dielectric layer 107 may include any suitable dielectric material for adhesive bonding. Alternatively, the dielectric layer 107 may be an etch stop layer (e.g., silicon nitride layer) between substrates 102a and 102b. The dielectric layer 107 is disposed over the top metal line 104 and may directly contact the top metal line 104 and the first substrate 102a. The second substrate 102b is disposed over the dielectric layer 107 and may embed or include other features not shown, such as active regions, interlayer dielectric layers, passivation layers, and/or other metal lines or vias. The first and second substrates 102a and 102b may include silicon (Si), or other semiconductor materials such as germanium (Ge), silicon carbide (SiC), silicon germanium (SiGe), or diamond. The first and second substrates 102a and 102b may also be collectively referred to as a substrate 102 that embeds the metal line 104 and the dielectric layer 107.

The method 200 at operation 204 forms a TSV trench 800 through the second substrate 102b and through the dielectric layer 107 (see FIG. 9). Operation 204 includes performing a multi-step etch process to form vertical (e.g., sidewalls s1 and s5) and tapered trench sidewalls (e.g., sidewalls s2, s3, and s5). The multi-etch process may use different etchants to separately etch the substrate 102a and the dielectric layer 107. In some embodiments, the multi-step etch process may be part of a dual-damascene process where the substrate 102b is patterned and etched in multiple steps to form the TSV trench 800 (e.g., forming the wider portion of the trench with a first etch mask, then forming the narrower portion of the trench by etching deeper with a second etch mask). In other embodiments, only one etch mask is used. Operation 204 is further explained with respect to steps 204-1 to 204-5 in FIG. 2B and FIGS. 5-9.

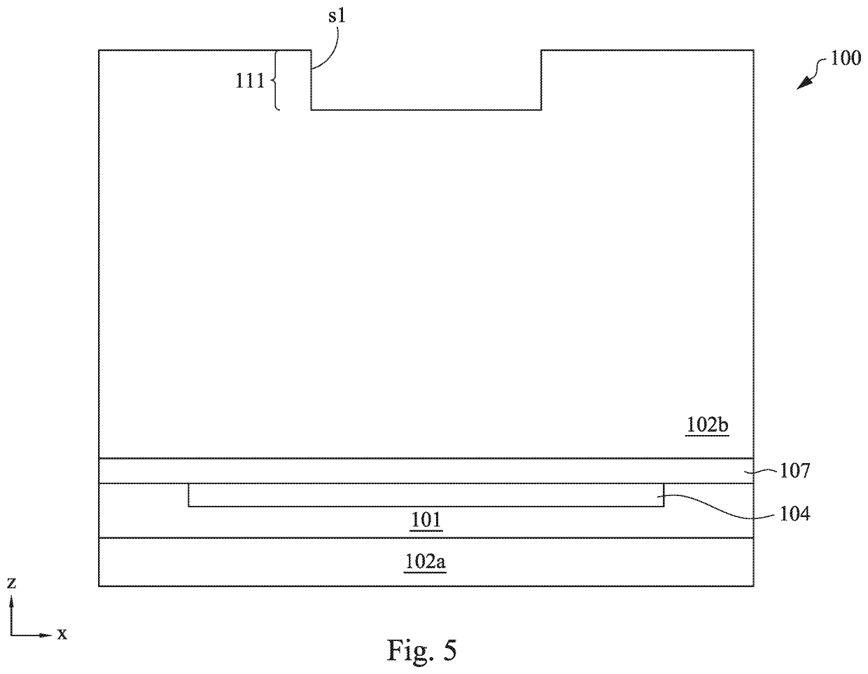

Referring now to FIG. 5, the operation 204 at step 204-1 performs a first etch at a first etch rate to form a first trench 111. The first trench 111 has vertical or near-vertical sidewalls that correspond to the first sidewalls s1. In an embodiment, step 204-1 includes forming a patterned mask layer over the substrate 102b and using the patterned mask layer as an etch mask when etching to form the first trench 111. The first trench 111 corresponds to the bulk portion 112 after the TSV 110 is formed.

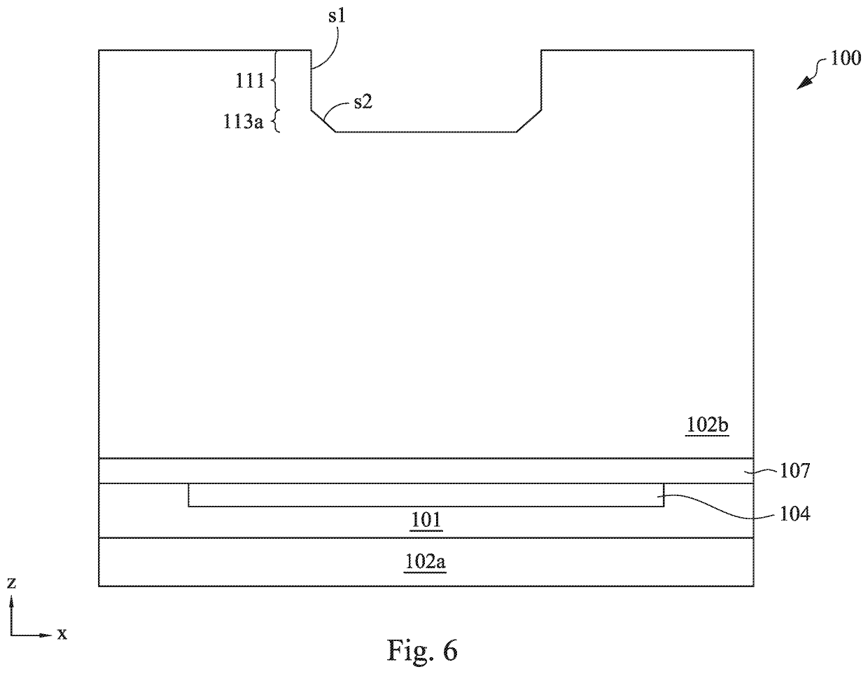

Referring now to FIG. 6, the operation 204 at step 204-2 performs a second etch at a second etch rate to form a second trench 113a. The second trench 113a has tapered sidewalls that correspond to the second sidewalls s2. In an embodiment, step 204-2 includes using the same patterned mask layer of step 204-1 as an etch mask. The second etch rate may be slower than the first etch rate, thereby producing the narrowing profile of the trench. The second trench 113a corresponds to the footing feature 114a after the TSV 110 is formed.

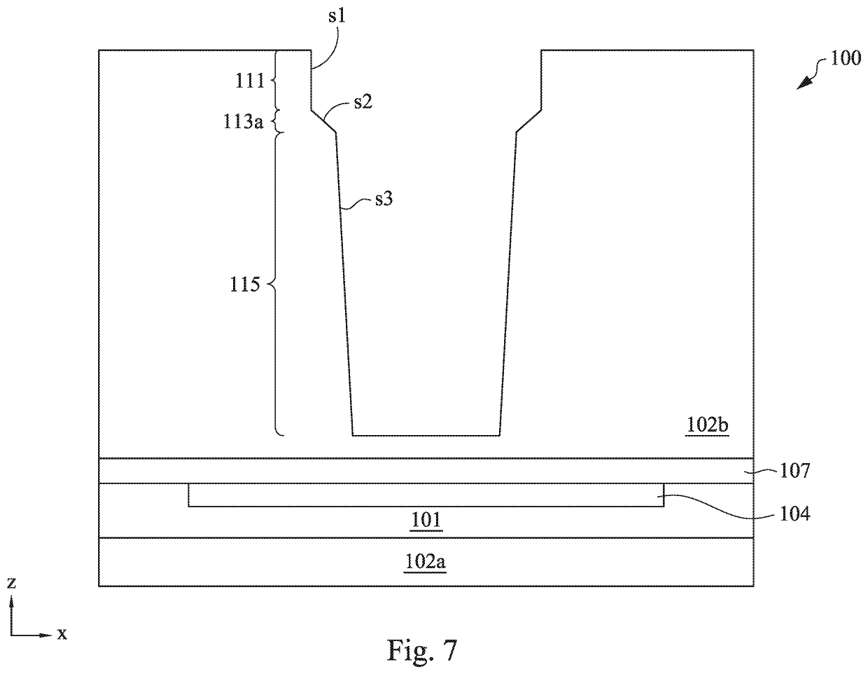

Referring now to FIG. 7, the operation 204 at step 204-3 performs a third etch at a third etch rate to form a third trench 115. The third trench 115 also has tapered sidewalls and they correspond to the third sidewalls s3. In an embodiment, step 204-3 includes using the same patterned mask layer of step 204-1 as an etch mask. In another embodiment, step 204-3 uses a different patterned mask layer as an etch mask. In this embodiment, different etch masks are used as part of a dual-damascene process to etch trenches corresponding to the wider top portion 110a of the TSV 110 and the narrower bottom portion 110b of the TSV 110. Whether one mask or two masks are used will depend on differences between the width W1 and W2. For example, if the difference is too big (i.e., greater than 1.5 μm), separate etch masks may be used. The third etch rate may be faster than the second etch rate but slower than the first etch rate, thereby producing a slightly slanted profile of the third trench 115. That is, the third trench 115 has sidewalls that are more slanted than sidewalls of the first trench 111 but less slanted than sidewalls of the second trench 113a. The third trench 115 corresponds to the bulk portion 116 after the TSV 110 is formed. Note that the third trench is deeper and penetrates through a greater amount of the substrate 102b than the first and second trenches 111 and 113a.

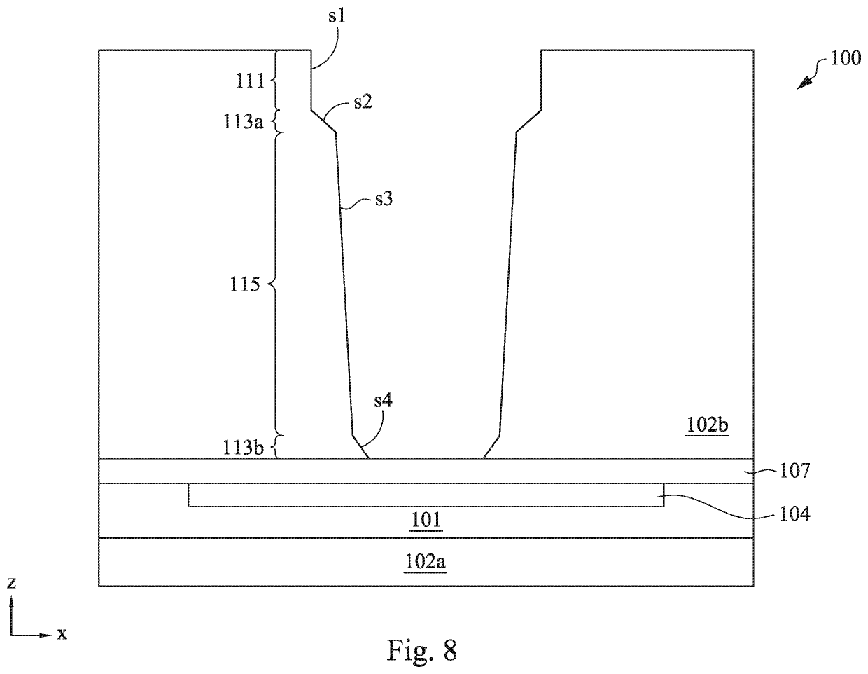

Referring now to FIG. 8, the operation 204 at step 204-4 performs a fourth etch at a fourth etch rate to form a fourth trench 113b. The fourth trench 113b has tapered sidewalls that correspond to the fourth sidewalls s4. In an embodiment, step 204-4 includes using the same patterned mask layer of step 204-3 as an etch mask. The fourth etch rate may be slower than the first etch rate, thereby producing the narrowing profile of the trench. In an embodiment, the fourth etch rate is also slower than the third etch rate to form a more slanted sidewall profile than the sidewalls of the third trench 115. In a further embodiment, the fourth etch rate is also faster than the second etch rate to form a less slanted sidewall profile than the sidewalls of the second trench 113a. That is, the fourth trench 113b may have sidewalls that are more slanted than sidewalls of the third trench 115 but less slanted than sidewalls of the second trench 113a. The fourth trench 113b corresponds to the footing feature 114b after the TSV 110 is formed. Note that the dielectric layer 107 may act as an etch stop layer, and after step 204-4, the dielectric layer 107 is exposed as shown.

Referring now to FIG. 9, the operation 204 at step 204-5 performs a fifth etch at a fifth etch rate to form a fifth trench 117. The fifth trench 117 has vertical or near-vertical sidewalls and they correspond to the fifth sidewalls s5. Note that step 204-5 etches through a dielectric material while steps 204-1 to 204-4 etches through a substrate material (e.g., silicon). Due to difference in etching selectivity, the fifth trench 117 may be formed by etching through the exposed portion of the dielectric layer 107 while not effecting the rest of the trenches 111, 113a, 115, and 113b. In an embodiment, step 204-5 includes using the same patterned mask layer of step 204-1 or step 204-3 as an etch mask. In another embodiment, the step 204-5 uses another etch mask different from the ones previously used. The fifth trench 117 exposes a top surface of the metal line 104. At the end of step 204-5, trenches 111, 113a, 115, 113b, and 117 are formed, which collectively forms the TSV trench 800.

Endpoint monitoring may be used when transitioning between the first etch at the first etch rate to the fifth etch at the fifth etch rate. This means that when a certain etch depth is reached, a new etch step having new etch rates (and/or other parameters) may be triggered. By adjusting etch rates and etching profiles, a single etch mask may be used to form the different width profiles.

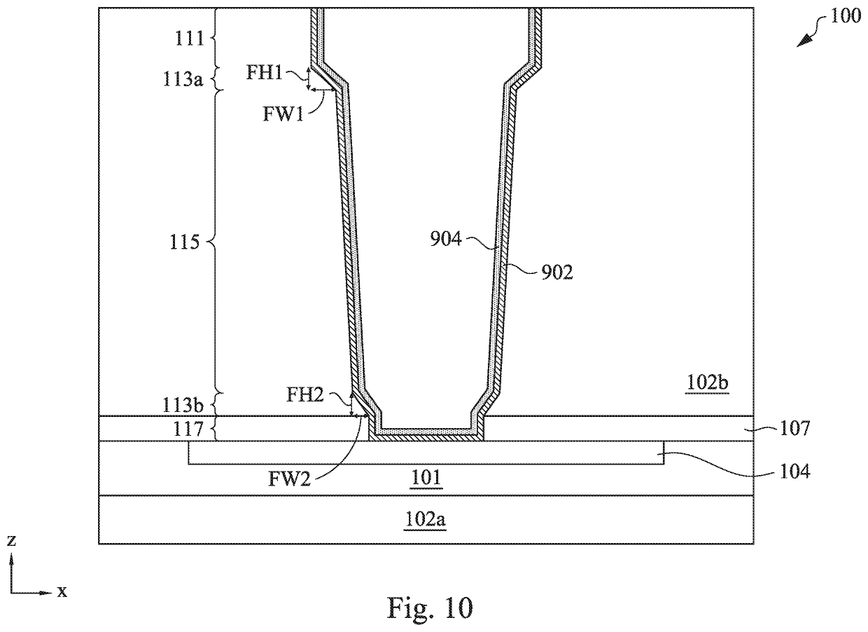

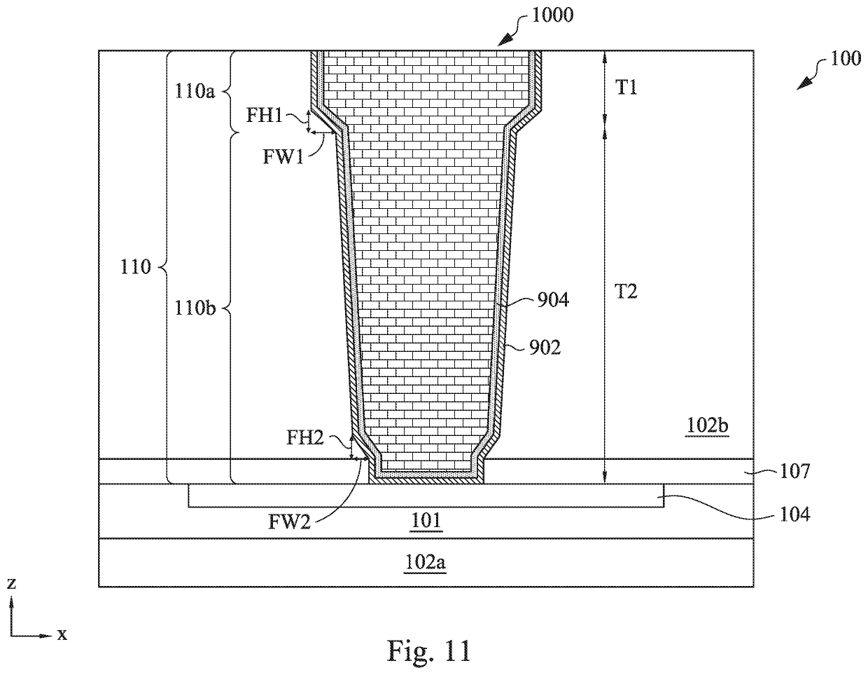

At operation 206, the method 200 forms a copper TSV 110 (see FIG. 11) in the TSV trench 800 by plating. The copper TSV 110 is formed to have high (111) crystal orientation. Referring now to FIG. 10, the formation of the copper TSV 110 may include first depositing a conductive barrier layer 902 and depositing a seed layer 904 over the conductive barrier layer 902. The conductive barrier layer 902 and the seed layer 904 prepares for the subsequent copper plating, and theses preparation layers may be deposited through conformal chemical vapor deposition (CVD) or physical vapor deposition (PVD) techniques. The conductive barrier layer 902 may include titanium (Ti), titanium nitride (TiN), tantalum (Ta), or tantalum nitride (TaN). The seed layer 904 may include manganese or other conductive materials such as ruthenium or cobalt. In an embodiment, the seed layer 904 may be a copper alloy such as copper manganese, copper ruthenium, or copper cobalt. In some embodiments, the seed layer 904 may be optional.

Referring now to FIG. 11, a copper fill 1000 is deposited in the TSV trench 800 and over the seed layer 904 (or the barrier layer 902 if there is no seed layer 904). After filling the trench, a planarization step may be performed, thereby forming the copper TSV 110 as shown. The copper fill 1000 is deposited through copper electroplating, which is an electrochemical process using an electrolyte bath. The copper electroplating process includes submerging a copper source and the TSV trench 800 in an electrolyte bath. The copper source acts as an anode and the TSV trench 800 acts as the cathode. By applying a bias voltage, the electrolyte bath allows copper particles to flow from the copper source to the surfaces of the TSV trench 800. As the copper particles continue to flow, a copper layer is plated and deposited. To control the plating rate and the texture of the copper fill, multiple additives and chemicals are used as part of the electrolyte bath. These additives may include levelers, accelerators, or suppressors. To facilitate bottom-up filling, suppressor and leveler additives may be used to reduce the deposition rate on the sides of the TSV trench 800 while accelerators are used to accelerate the deposition rate on the bottom surface and lower portions of the TSV trench 800.

Due to the TSV trench 800 having the various tapered and tilted sidewalls as described above, by adjusting the electrolyte additives and the bias voltage, the copper fill 1000 is plated such that the crystalline structure of the copper fill 1000 has high (111) crystal orientation. As shown, the tilted and tapered sidewalls gradually opens the trench opening such that there are no abrupt changes in width. The tilted sidewalls and the tapered changes between width profiles each promote uniform crystalline growth throughout the TSV trench 800. For example, referring back to FIG. 1, the footing feature 114b gradually opens up the TSV to a big enough width for preferential crystal growth, then the bulk portion 116 has a reduced tilt to continue facilitate preferential crystal growth, then the footing feature 114b tapers the trench opening to transition to the wider top portion dimension W1. Note that the various slanted and tapered features also function to redirect and spread out thermal stress, thereby also reducing thermal protrusion. In an embodiment, a same additive setting and a same bias voltage setting is used throughout the copper plating process. In another embodiment, since the trench opening and the width profiles becomes bigger from bottom to top, a different additive setting and a different bias voltage may be applied starting at a middle point of the TSV trench 800 (e.g., when the copper fills to the width W3 in FIG. 1). In an embodiment, the bias voltage changes from applying a current at 1 amp per square decimeter (ASD) to 3 ASD. Such change may also facilitate faster deposition time.

To see benefits in avoiding copper protrusion due to thermal loading, the copper fill 1000 should have at least 85% (111) crystal orientation. For example, the resulting TSV 110 may have 85% (111) crystal orientation, 7% (110) crystal orientation, and 8% (001) orientation. However, due to the unique TSV via trench structure, by adjusting additive and bias voltage parameters, the copper fill 1000 can achieve over 97% (111) crystal orientation. For example, the resulting TSV 110 may have 97% (111) crystal orientation, 1.5% (110) crystal orientation, and 1.5% (001) crystal orientation. Especially for high performance ICs sensitive to defects caused by thermal loadings, copper fill having over 97% (111) crystal orientation can be effective in avoiding protrusion defect concerns. In an embodiment, for a TSV having over 97% (111) crystal orientation, the copper grain growth of the TSV remains unchanged even after thermal loadings of 300° C. for an hour.

Still referring to FIG. 11, the formed TSV 110 may have a substantially all-horizontal texture. That is, the grains of the copper fill orient (or substantially orient) in an all-horizontal direction. By all-horizontal texture, the present disclosure contemplates that all grains in the copper fill are aligned in the horizontal direction. The all-horizontal texture may be realized by the applied bias voltage and the additives used during electroplating. For example, a single additive setting and a single bias voltage setting was used to produce the substantially all-horizontal texture.

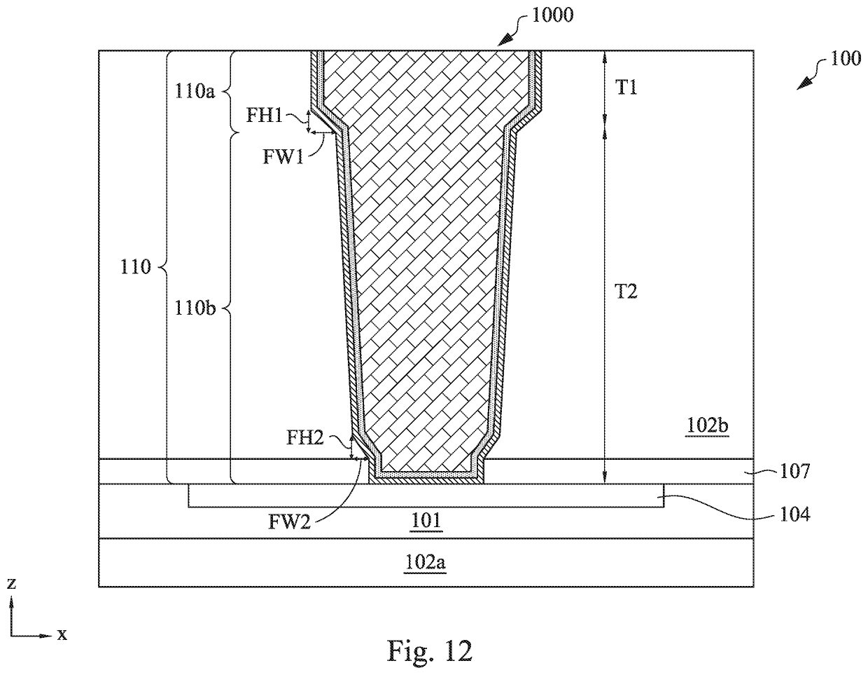

FIGS. 12-14 illustrate other embodiments of the TSV 110 having different texture configurations than the TSV 110 in FIG. 11. The similar features are not described again for the sake of brevity. Note that despite different texture configurations, each of the TSV 110 in all of FIGS. 12-14 also achieves high (111) crystal orientation, such as at least 85% and up to over 97%. The different texture configurations may be used in different semiconductor structures to achieve thermal stability and prevent metal protrusion issues.

Referring now to FIG. 12, the formed TSV 110 may have a substantially all-slanted texture. That is, the grains of the copper fill orient (or substantially orient) in an all-slanted direction. By all-slanted texture, the present disclosure contemplates all grains in the copper fill are substantially aligned in the slanted direction (e.g., between 0 to 95 degrees, such as 45 degrees). The all-slanted texture may be realized by the applied bias voltage and the additives used during electroplating. For example, like in FIG. 11, a single additive setting and a single bias voltage setting was used to produce the substantially all-slanted texture. However, the texture is all-slanted instead of all-horizontal due to applying a different bias voltage and/or a different additive setting than the one used to form the TSV 110 in FIG. 11.

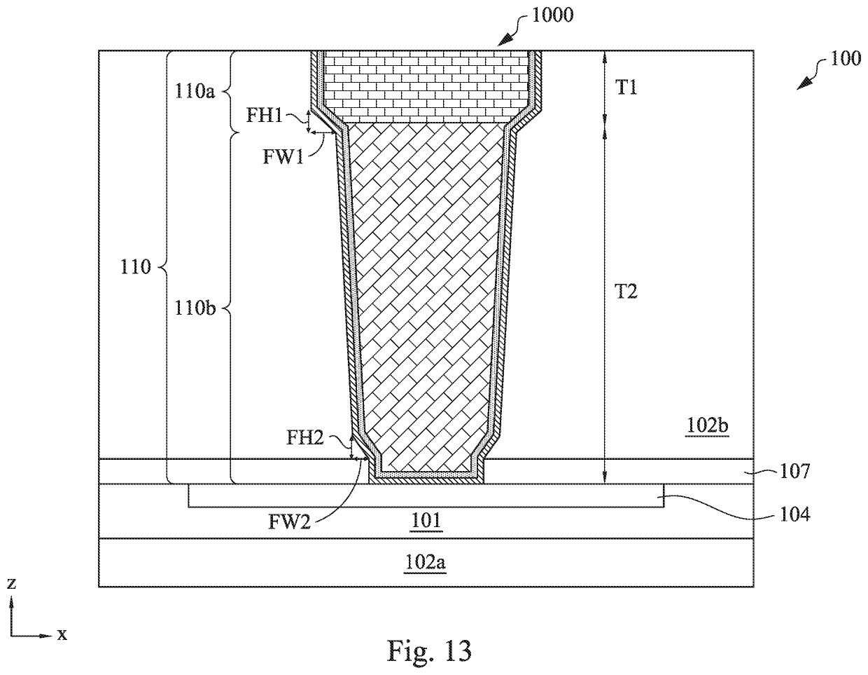

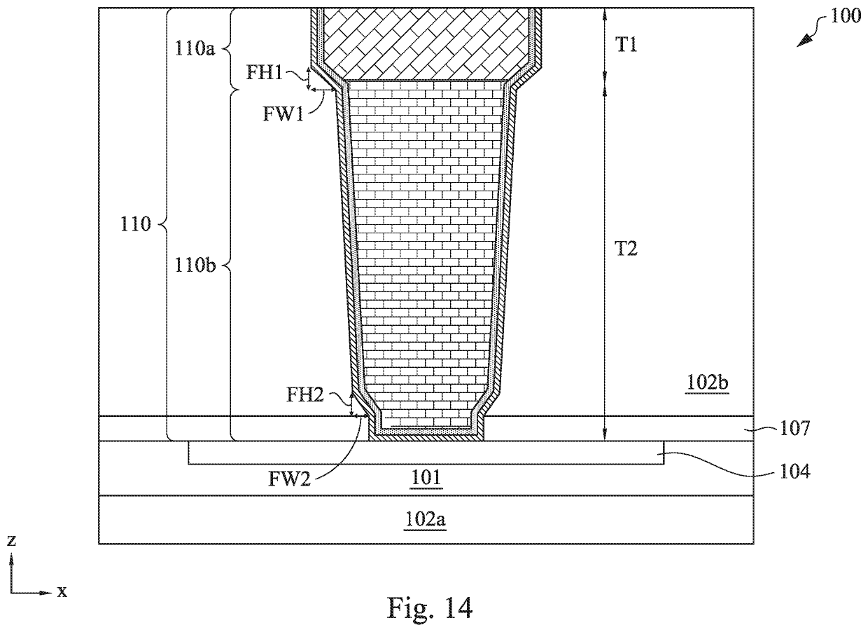

Referring now to FIGS. 13-14, the formed TSV 110 may have a mixed texture having a first portion with substantially all-horizontal texture and a second portion with substantially all-slanted texture. That is, the grains of the copper fill orient (or substantially orient) in both an all-horizontal direction and an all-slanted direction. The mixed texture may be realized by changing the applied bias voltage and/or the additives from a first setting to a second setting during electroplating. For example, a first bias voltage and additive setting was used during electroplating for the bottom portion 110b, and a second bias voltage and additive setting was used during electroplating for the top portion 110a. As such, as shown in FIG. 13, the bottom portion 110b may have a substantially all-slanted texture and the top portion 110a may have a substantially all-horizontal texture. Alternatively, now referring to FIG. 14, the bottom portion 110b may have a substantially all-horizontal texture and the top portion 110a may have a substantially all-slanted texture.

Although not intended to be limiting, the present disclosure offers advantages in forming a TSV. One example advantage is forming a TSV having various slanted and tapered footing features to facilitate high (111) crystal orientations. Another example advantage is forming a TSV with sidewalls that gradually open up to spread out thermal stress.

One aspect of the present disclosure pertains to a semiconductor structure. The semiconductor structure includes a metal line over a first substrate, a second substrate over the metal line, and a through-via penetrating through the second substrate and landing on the metal line. The through-via includes a copper fill having at least 85% (111) crystal orientation. The through-via includes a top portion with a first top width over a bottom portion with a second top width that is smaller than the first top width, and the top portion includes a first bulk portion over a first footing feature. The first bulk portion has first sidewalls, the first footing feature has second sidewalls, and the second sidewalls slant inwards from the first sidewalls to narrow the through-via from the first top width of the top portion to the second top width of the bottom portion.

In an embodiment, all grains in the through-via are substantially aligned in the horizontal direction. In an embodiment, a first portion of the through-via has a first texture direction, a second portion of the through-via has a second texture direction, and the first texture direction is different from the second texture direction.

In an embodiment, the first top width of the top portion ranges between 1.4 μm to 10 μm, and the second top width of the bottom portion ranges between 0.6 μm to 8 μm. In an embodiment, the top portion has a top height that ranges between 0.5 μm to 2.5 μm, and the first footing feature has a first foot height that ranges between 0.1 μm to 1 μm.

In an embodiment, the bottom portion includes a second bulk portion over a second footing feature. The second bulk portion has third sidewalls, the second footing feature has fourth sidewalls, and the fourth sidewalls slant inwards from the third sidewalls to narrow the through-via from a first bottom width of the second bulk portion to a second bottom width of the second footing feature.

In a further embodiment, the first bottom width of the second bulk portion ranges between 0.4 μm to 7 μm, and the second bottom width of the second footing feature ranges between 0.3 μm to 6.3 μm. In an embodiment, the third sidewalls are titled towards a center of the through-via. In an embodiment, the bottom portion further includes a landing portion between the second footing feature and the metal line, the landing portion has fifth sidewalls.

In an embodiment, the through-via includes a copper fill having at least 97% (111) crystal orientation.

Another aspect of the present disclosure pertains to a semiconductor structure. The semiconductor structure includes a metal line over a first substrate, a dielectric layer over the metal line, a second substrate over the dielectric layer, and a through-via penetrating through the second substrate and the dielectric layer to land on the metal line. The through-via includes a wider top portion over a narrower bottom portion. The top portion includes a first bulk portion over a first footing feature, the first bulk portion has first sidewalls, the first footing feature has second sidewalls, and the second sidewalls slant inwards from the first sidewalls to narrow the through-via from a first width to a second width. The bottom portion includes a second bulk portion over a second footing feature, the second bulk portion has third sidewalls, the second footing feature has fourth sidewalls, and the fourth sidewalls slant inwards from the third sidewalls to narrow the through-via from a third width to a fourth width.

In an embodiment, the first width is greater than the second width by a first width difference, the third width is greater than the fourth width by a second width difference, and the first width difference is greater than the second width difference.

In an embodiment, the through-via includes a copper fill that has a substantially all-horizontal or all-slanted texture with at least 97% (111) crystal orientation.

In an embodiment, the second width is greater than the third width due to the third sidewalls slanting inwards from the second sidewalls to the fourth sidewalls. In a further embodiment, the second and the fourth sidewalls are more slanted inwards than the third sidewalls.

In an embodiment, the bottom portion further includes a landing portion between the second footing feature and the metal line, the landing portion has fifth sidewalls.

Another aspect of the present disclosure pertains to a method of forming a semiconductor structure. The method includes receiving a workpiece having a first metal over a first substrate and a second substrate over the first substrate, forming a through-via trench by etching through the second substrate to expose the first metal, the through-via trench having a wider top portion over a narrower bottom portion, and forming a through-via in the through-via trench by copper plating. The copper plating fills the through-via trench with a copper layer having at least 85% (111) crystal orientation.

In an embodiment, the forming of the through-via trench includes performing a multi-step etch process to form vertical and tapered trench sidewalls. The vertical trench sidewalls are formed by a first etch process, the tapered trench sidewalls are formed by a second etch process, and the first etch process applies a faster etch rate than the second etch process.

In a further embodiment, the multi-step etch process uses a single etch mask to form the wider top portion of the through-via trench and the narrower bottom portion of the through-via trench. In an embodiment, the multi-step etch process uses a first etch mask to form the wider top portion of the through-via trench and a second etch mask to form the narrower bottom portion of the through-via trench.

The details of the method and structure of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a metal line over a first substrate;
a second substrate over the metal line; and
a through-via penetrating through the second substrate and landing on the metal line,
wherein the through-via includes a copper fill having at least 85% (111) crystal orientation,
wherein the through-via includes a top portion with a first top width over a bottom portion with a second top width that is smaller than the first top width, and the top portion includes a first bulk portion over a first footing feature,
wherein the first bulk portion has first sidewalls, the first footing feature has second sidewalls, and the second sidewalls slant inwards from the first sidewalls to narrow the through-via from the first top width of the top portion to the second top width of the bottom portion.

2. The semiconductor structure of claim 1, wherein all grains in the through-via are substantially aligned in the horizontal direction.

3. The semiconductor structure of claim 1, wherein a first portion of the through-via has a first texture direction, a second portion of the through-via has a second texture direction, and the first texture direction is different from the second texture direction.

4. The semiconductor structure of claim 1, wherein the first top width of the top portion ranges between 1.4 μm to 10 μm, and the second top width of the bottom portion ranges between 0.6 μm to 8 μm.

5. The semiconductor structure of claim 1, wherein the top portion has a top height that ranges between 0.5 μm to 2.5 μm, and the first footing feature has a first foot height that ranges between 0.1 μm to 1 μm.

6. The semiconductor structure of claim 1,
wherein the bottom portion includes a second bulk portion over a second footing feature,
wherein the second bulk portion has third sidewalls, the second footing feature has fourth sidewalls, and the fourth sidewalls slant inwards from the third sidewalls to narrow the through-via from a first bottom width of the second bulk portion to a second bottom width of the second footing feature.

7. The semiconductor structure of claim 6, wherein the first bottom width of the second bulk portion ranges between 0.4 μm to 7 μm, and the second bottom width of the second footing feature ranges between 0.3 μm to 6.3 μm.

8. The semiconductor structure of claim 6, wherein the third sidewalls are titled towards a center of the through-via.

9. The semiconductor structure of claim 6,
wherein the bottom portion further includes a landing portion between the second footing feature and the metal line, the landing portion has fifth sidewalls.

10. The semiconductor structure of claim 1, wherein the through-via includes a copper fill having at least 97% (111) crystal orientation.

11. A semiconductor structure, comprising:
a metal line over a first substrate;
a dielectric layer over the metal line;
a second substrate over the dielectric layer; and
a through-via penetrating through the second substrate and the dielectric layer to land on the metal line,
wherein the through-via includes a wider top portion over a narrower bottom portion,
the top portion includes a first bulk portion over a first footing feature, the first bulk portion has first sidewalls, the first footing feature has second sidewalls, and the second sidewalls slant inwards from the first sidewalls to narrow the through-via from a first width to a second width,
the bottom portion includes a second bulk portion over a second footing feature, the second bulk portion has third sidewalls, the second footing feature has fourth sidewalls, and the fourth sidewalls slant inwards from the third sidewalls to narrow the through-via from a third width to a fourth width.

12. The semiconductor structure of claim 11, wherein the first width is greater than the second width by a first width difference, the third width is greater than the fourth width by a second width difference, and the first width difference is greater than the second width difference.

13. The semiconductor structure of claim 11, wherein the through-via includes a copper fill that has a substantially all-horizontal or all-slanted texture with at least 97% (111) crystal orientation.

14. The semiconductor structure of claim 11, wherein the second width is greater than the third width due to the third sidewalls slanting inwards from the second sidewalls to the fourth sidewalls.

15. The semiconductor structure of claim 14, wherein the second and the fourth sidewalls are more slanted inwards than the third sidewalls.

16. The semiconductor structure of claim 11,
wherein the bottom portion further includes a landing portion between the second footing feature and the metal line, the landing portion has fifth sidewalls.

17. A method of forming a semiconductor structure, comprising:
receiving a workpiece having a first metal over a first substrate and a second substrate over the first substrate;
forming a through-via trench by etching through the second substrate to expose the first metal, the through-via trench having a wider top portion over a narrower bottom portion; and
forming a through-via in the through-via trench by copper plating, wherein the copper plating fills the through-via trench with a copper layer having at least 85% (111) crystal orientation.

18. The method of claim 17,
wherein the forming of the through-via trench includes performing a multi-step etch process to form vertical and tapered trench sidewalls,
wherein the vertical trench sidewalls are formed by a first etch process, the tapered trench sidewalls are formed by a second etch process, and the first etch process applies a faster etch rate than the second etch process.

19. The method of claim 18, wherein the multi-step etch process uses a single etch mask to form the wider top portion of the through-via trench and the narrower bottom portion of the through-via trench.

20. The method of claim 18, wherein the multi-step etch process uses a first etch mask to form the wider top portion of the through-via trench and a second etch mask to form the narrower bottom portion of the through-via trench.
